(19) United States
(12) Patent Application Publication
(10) Pub. No.: US 2026/0205099 A1
(43) Pub. Date: Jul. 16, 2026

(54) SEMICONDUCTOR DEVICE

(71) Applicant: RENESAS ELECTRONICS CORPORATION, Tokyo (JP)

(72) Inventor: Mitsuhiko IGARASHI, Tokyo (JP)

(21) Appl. No.: 19/422,659

(22) Filed: Dec. 17, 2025

(30) Foreign Application Priority Data
Jan. 10, 2025 (JP) 2025-004051

(51) Int. Cl. H03K 3/011; H03K 3/03

(52) U.S. Cl. CPC H03K 3/011; H03K 3/0315

(57) ABSTRACT

A semiconductor device includes: an oscillator circuit including a plurality of logic gate groups connected in series; a frequency counter measuring an oscillation frequency of the oscillator circuit; and a comparator comparing a reference value and the oscillation frequency of the oscillator circuit measured by the frequency counter. Each of the logic gate groups includes first to third logic gates each made of a transistor and connected in series. A first fan-out number of the first logic gate is larger than a second fan-out number of the second logic gate and the third logic gate. The first to third logic gates have the same driving force from one another.

### CROSS-REFERENCE TO RELATED APPLICATION

The disclosure of Japanese Patent Application No. 2025-004051 filed on January 10, 2025, including the specification, drawings and abstract is incorporated herein by reference in its entirety.

### BACKGROUND

The present disclosure relates to a semiconductor device, and more specifically relates to a semiconductor device for detecting a deterioration of a semiconductor element due to hot carriers.

In recent years, integration of semiconductor devices has further advanced in accordance with the development of microfabrication process techniques. On the other hand, decrease in a voltage of a power supply voltage due to the microfabrication of such a semiconductor device becomes a problem. Thus, a field intensity of an internal element configuring the semiconductor device tends to increase. Particularly, metal-oxide-semiconductor (MOS) transistors cause hot carrier injection (also referred to as HCI below) phenomenon in which the hot carriers caused by the increase in the field intensity are injected into a gate insulating film. This hot carrier injection phenomenon has a problem that is a deterioration (increase) of a threshold voltage of the MOS transistor.

There is disclosed technique listed below.

Patent Document 1 Japanese Unexamined Patent Application Publication No. 2017-34207

In this regard, for example, the Patent Document 1 proposes a system for detecting the deterioration of the semiconductor element due to the HCI of the semiconductor element.

### SUMMARY

Meanwhile, a system made of a combination of an inverter with a large driving force and an inverter with a small driving force is proposed for the above system. However, the inverter with the large driving force consumes a large amount of power.

The present disclosure has been made in order to solve the above problem, and an objective of the present disclosure is to accurately detect a deterioration of a semiconductor element due to HCI while reducing power consumption.

Other objects and novel characteristics will become apparent from the description of the present specification and the accompanying drawings.

A semiconductor device according to the present disclosure includes: an oscillator circuit including a plurality of logic gate groups connected in series; a frequency counter measuring an oscillation frequency of the oscillator circuit; and a comparator comparing a reference value and an oscillation frequency of the oscillator circuit measured by the frequency counter. Each of the logic gate groups includes first to third logic gates each made of a transistor and connected in series. A first fan-out number of the first logic gate is larger than a second fan-out number of the second logic gate and the third logic gate. The first to third logic gates have the same driving force from one another.

A semiconductor device according to another aspect of the present disclosure includes: a first oscillator circuit being capable of suppressing a deterioration of a transistor due to hot carrier injection by an oscillation; a first frequency counter measuring an oscillation frequency of the first oscillator circuit; and a first computer circuit calculating a difference between a first reference value and the oscillation frequency of the first oscillator circuit measured by the first frequency counter. The semiconductor device further includes: a second oscillator circuit being capable of suppressing a deterioration of a transistor due to hot carrier injection by an oscillation; a second frequency counter measuring an oscillation frequency of the second oscillator circuit; and a second computer circuit calculating a difference between a second reference value and the oscillation frequency of the second oscillator circuit measured by the second frequency counter. The semiconductor device further includes a detector circuit detecting the deterioration due to the hot carrier injection, based on the differences calculated by the first computer circuit and the second computer circuit.

In a semiconductor device according to an embodiment, HCI deterioration of a semiconductor element can be accurately detected while power consumption is reduced.

### BRIEF DESCRIPTIONS OF THE DRAWINGS

FIG. 1 is a diagram for explaining a configuration of a semiconductor device 1 according to a first embodiment of the present disclosure.

FIG. 2 is a diagram illustrating a temporal change of an oscillation frequency of an oscillator circuit according to the first embodiment of the present disclosure.

FIG. 3 is a diagram illustrating an exemplary configuration of an oscillator circuit 204 (ring oscillator) according to the first embodiment.

FIG. 4 is a diagram for explaining a configuration of a NAND gate “NAD” according to the first embodiment.

FIG. 5 is a diagram for explaining temporal change of each node voltage of the oscillator circuit 204 according to the first embodiment.

FIG. 6 is a diagram illustrating an exemplary configuration of an oscillator circuit 205 according to a second embodiment.

FIG. 7 is a diagram for explaining a NOR gate “NR” according to the second embodiment.

FIG. 8 is a diagram illustrating an exemplary configuration of an oscillator circuit 208 according to a modification example of the second embodiment.

FIG. 9 is a diagram for explaining a NAND gate “ND” according to a modification example of the second embodiment.

FIG. 10 is a diagram illustrating an exemplary configuration of an oscillator circuit 210 according to a third embodiment.

FIG. 11 is a diagram for explaining a NOR gate “NRD” according to the third embodiment.

FIG. 12 is a diagram for explaining differences in lifetime between P-channel MOS transistors PT1 and PT2 due to HCI.

FIG. 13 is a diagram illustrating an exemplary configuration of an oscillator circuit 212 according to a modification example of the third embodiment.

FIG. 14 is a diagram for explaining a NAND gate “NDD” according to a modification example of the third embodiment.

FIG. 15 is a diagram illustrating an exemplary configuration of an oscillator circuit 214 according to a fourth embodiment.

FIG. 16 is a diagram for explaining a circuit configuration (during no oscillation) of a complex gate “G” according to the fourth embodiment.

FIG. 17 is a diagram for explaining a circuit configuration (during oscillation) of the complex gate G according to the fourth embodiment.

FIG. 18 is a diagram for explaining causes of a frequency shift of an oscillator circuit according to a comparative example.

FIG. 19 is a diagram for explaining causes of a frequency shift of the oscillator circuit 214 according to the fourth embodiment.

FIG. 20 is a diagram for explaining a system for detecting HCI deterioration, based on a combination of oscillator circuits according to the fourth embodiment.

FIG. 21 is a diagram for explaining a system for detecting HCI deterioration, based on a combination of oscillator circuits according to a modification example of the fourth embodiment.

### DETAILED DESCRIPTION

Hereinafter, embodiments will be described in detail with reference to the drawings. Note that the same or similar components in the drawings are denoted with the same reference symbols, and the repetitive description thereof is omitted.

### FIRST EMBODIMENT

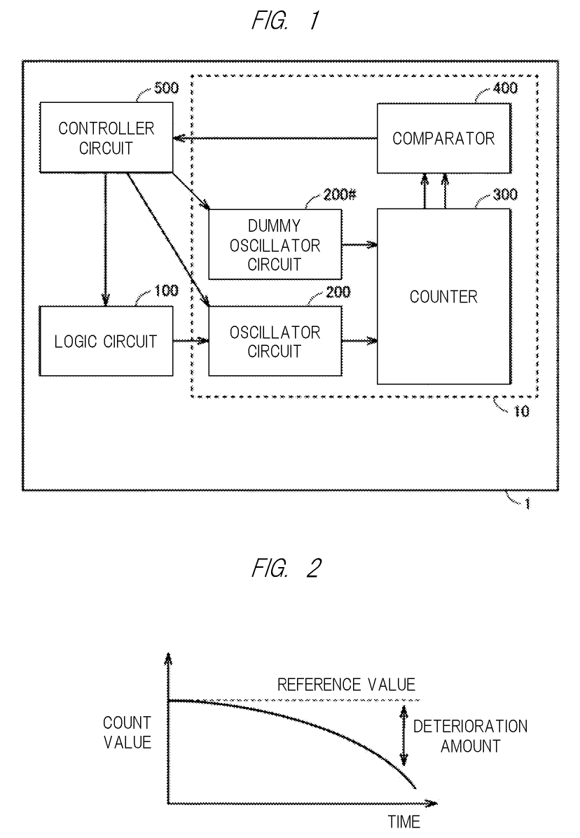

FIG. 1 is a diagram for explaining a configuration of a semiconductor device 1 according to a first embodiment of the present disclosure. With reference to FIG. 1, the semiconductor device 1 includes a logic circuit 100, a control circuit 500, and a detector circuit 10. The logic circuit 100 performs a predetermined logic calculation in response to an instruction from the control circuit 500. The control circuit 500 totally controls the semiconductor device 1. The detector circuit 10 detects the HCI deterioration of the semiconductor element of the semiconductor device 1.

The detector circuit 10 includes an oscillator circuit 200, a dummy oscillator circuit 200#, a counter 300, and a comparator 400.

In the present example, a case of use of, for example, a ring oscillator for the oscillator circuit 200 is described. The oscillator circuit 200 oscillates because of being made of an odd number of logic gates. The oscillator circuit 200 oscillates in response to an instruction from the control circuit 500. For example, a clock operation of the semiconductor device 1 or the like is performed in response to an oscillation signal from the oscillator circuit 200. The control circuit 500 can instruct the oscillator circuit 200 to oscillate or to stop oscillating. The counter 300 counts input oscillation signals of the oscillator circuit 200, and measures an oscillation frequency of the oscillator circuit 200. The measured oscillation frequency is output to the comparator 400.

The dummy oscillator circuit 200# has the same circuit configuration as that of the oscillator circuit 200, and does not oscillate during normal time but oscillates during detection (measurement) in response to an instruction of the control circuit 500. The dummy oscillator circuit 200# is not oscillated during normal time, and thus, the deterioration of the semiconductor element is suppressed. The counter 300 counts input oscillation signals of the dummy oscillator circuit 200#, and measures an oscillation frequency of the dummy oscillator circuit 200#. The measured oscillation frequency is output to the comparator 400.

The comparator 400 compares the oscillation frequency of the oscillator circuit 200 output by the counter 300 and the oscillation frequency of the dummy oscillator circuit 200# output by the counter 300. When a difference between the oscillation frequency of the oscillator circuit 200 and the oscillation frequency of the dummy oscillator circuit 200# reaches a predetermined difference, the comparator 400 outputs the result to the control circuit 500. The control circuit 500 determines the deteriorated lifetime of the semiconductor device 1 in response to the result from the comparator 400. In the present example, the case with the dummy oscillator circuit 200# to use the system for measuring the reference value of the oscillation frequency as a comparison criterion has been described. This manner can achieve the determination of the deteriorated lifetime of the semiconductor device 1 based on the oscillation frequency of the oscillator circuit 200 also in consideration of the shift of the oscillation frequency (reference value) of the dummy oscillator circuit 200# due to environmental variations. Note that the present invention is not limited to this. For example, a system being without the dummy oscillator circuit 200# and performing comparison with an initial value (predetermined value) of the oscillation frequency of the oscillator circuit 200 previously stored in the comparator 400 may be employed. The initial value may be stored in, for example, a nonvolatile memory (not illustrated).

The control circuit 500 is connected to the logic circuit 100, the oscillator circuit 200, and the dummy oscillator circuit 200#. The control circuit 500 controls oscillations of the oscillator circuits 200 and 200#. To a display apparatus (not illustrated) or the like, the control circuit 500 outputs an alarm indicating that the lifetime reaches to the deteriorated lifetime of the semiconductor device 1 in response to a signal (indicating that the oscillation frequency of the oscillator circuit 200 is lower than the reference value by the predetermined difference or more) based on a comparison result from the comparator 400. In another circumstances, the control circuit 500 may be included in the detector circuit 10, the logic circuit 100, or the like.

Along with circuit operations of the oscillator circuit 200, the transistor configuring the oscillator circuit 200 is deteriorated by the HCI, and its operation speed is decreased. Thus, the oscillation frequency of the oscillator circuit 200 is decreased.

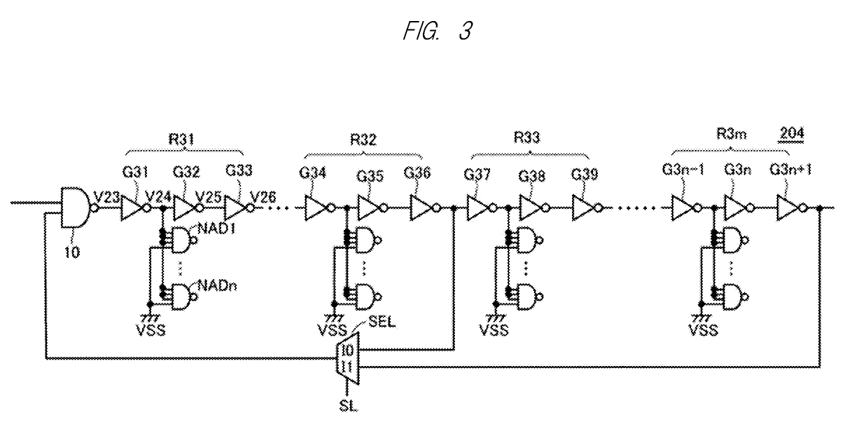

FIG. 2 is a diagram illustrating a temporal change in the oscillation frequency of the oscillator circuit according to the first embodiment of the present disclosure. With reference to FIG. 2, during the operation of the oscillator circuit 200, the oscillation frequency of the oscillator circuit 200 is decreased. Thus, the detector circuit 10 compares the reference value and the oscillation frequency of the oscillator circuit 200, thereby determining the degree of deterioration of the transistor configuring the oscillator circuit 200. For example, the reference value corresponds to the oscillation frequency of the dummy oscillator circuit 200#.

When the oscillator circuit 200 is configured to operate only during the operation of the logic circuit 100, the detector circuit 10 may determine the degree of deterioration of the transistor configuring the logic circuit 100.

FIG. 3 is a diagram illustrating an exemplary configuration of an oscillator circuit 204 (ring oscillator) according to the first embodiment. With reference to FIG. 3, the oscillator circuit 202 according to the first embodiment includes a plurality of logic gate groups. Specifically, the oscillator circuit 202 includes a NAND gate 10 and logic gate groups R31 to R3m. The NAND gate 10 and the logic gate groups R31 to R3m are connected in series.

The logic gate groups R31 to R3m include first to third logic gates made of transistors and connected in series, respectively. The first fan-out number of the first logic gate is larger than the second fan-out number of the second and third logic gates, and the first to third logic gates are set to have the same driving force as one another.

In the present example, the logic gate group R31 includes inverters G31 to G33 with the same driving force. The inverter G32 and 4-input NAND gates NAD1 to NADn, the number of which is “n”, are connected in parallel.

Three input terminals of each of the 4-input NAND gates NAD1 to NADn receive the output of the inverter arranged at their previous level as their inputs. A fixed voltage VSS is connected to the remaining one input terminal.

The output of the inverter G31 is connected to the inverter G32 and the 4-input NAND gates NAD1 to NADn. Thus, the fan-out number of the inverter G31 is “n + 1.” The term “fan-out number” means the number of logic gates to which the output of the logic gate is connected. The output of the inverter G32 is connected to the inverter G33. Thus, the fan-out number of the inverter G32 is 1. The fan-out number of the inverter G33 is 1.

The outputs of the 4-input NAND gates NAD1 to NADn are open. These NAND gates are connected in parallel in order to increase the total capacity of the output node of the inverter G31. Thus, the outputs of these NAND gates may be open or may be connected to the inverter G33 arranged at their post level.

The capacity of the output of the inverter G31 increases in proportional to the number of logic gates connected in parallel.

The configurations of the other logic gate groups R32 to R3m are similar to that of the logic gate group R31, and thus, will not be repeatedly described in detail.

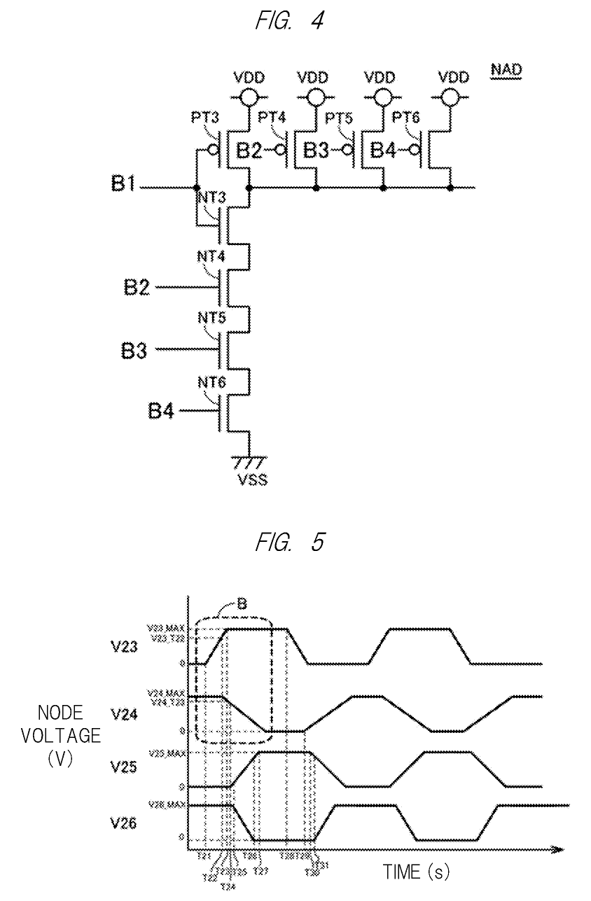

FIG. 4 is a diagram for explaining a configuration of a NAND gate “NAD” according to the first embodiment. With reference to FIG. 4, the NAND gate NAD includes P-channel MOS transistors PT3 to PT6 and N-channel MOS transistors NT3 to NT6. The P-channel MOS transistors PT3 to PT6 are connected in parallel between the power supply voltage VDD and the output node. The N-channel MOS transistors NT3 to NT6 are connected in series between the output node and the fixed voltage VSS. The P-channel MOS transistor PT3 and the N-channel MOS transistor NT3 are connected to a node B1. The P-channel MOS transistor PT4 and the N-channel MOS transistor NT4 are connected to a node B2. The P-channel MOS transistor PT5 and the N-channel MOS transistor NT5 are connected to a node B3. The P-channel MOS transistor PT6 and the N-channel MOS transistor NT6 are connected to a node B4.

In the present example, the nodes B1 to B3 are connected to the output of the inverter G arranged at their previous level. The node B4 is connected to the fixed voltage VSS.

FIG. 5 is a diagram for explaining a temporal change of each node voltage of the oscillator circuit 204 according to the first embodiment. With reference to FIG. 5, the present example show a node voltage V23 of the input node of the inverter G31, a node voltage V24 of the input node of the inverter G32, a node voltage V25 of the input node of the inverter G33, and a node voltage V26 of the output node of the inverter G33 in the logic gate group R31.

At time T21, the node voltage V23 starts changing (rising) from 0 (Low) to V23_MAX (High) in response to an output signal from the NAND gate 10. After the elapse of a predetermined time, at time T28, the node voltage V23 starts changing (falling) from High to Low in response to an output signal from the NAND gate 10.

The rising and the falling gradients of the node voltage V23 are steep. The reason for this is that the fan-out number of the NAND gate 10 is 1.

At time T22, the node voltage V24 starts falling from V24_MAX (High) to 0 (Low). After the elapse of a predetermined time, at time T29, the node voltage V24 starts rising from Low to High.

The rising and the falling gradients of the node voltage V24 are gentle. The reason for this is that the fan-out number of the inverter G31 is “n + 1” such that a load capacity is large.

At time T22, the node voltage of the output of the inverter G31 is V24_MAX that is the maximum value. On the other hand, the node voltage V23_T22 of the input of the inverter G31 is close to V23_MAX. The node voltage V23_T22 is high. The reason for this is that the rising gradient of the node voltage V23 is steep. Thus, at time T22, the HCI deterioration of the inverter G31 is large.

At time T23, the node voltage of the input of the inverter G31 is V23_MAX that is the maximum value. On the other hand, the node voltage V24_T23 of the output of the inverter G31 is close to V24_MAX. The node voltage V24_T23 is high. The reason for this is that the falling gradient of the node voltage V24 is gentle. Thus, at time T23, the HCI deterioration of the inverter G31 is large. That is, the HCI deterioration of the inverter G31 is large in the period from time T22 to time T23.

As a property of the transistor configuring the logic gate, the node voltage of the output of the logic gate is influenced by the node voltage of the input thereof. For example, when a temporal change (gradient) of the node voltage of the input of the logic gate is gentle, the gradient of the node voltage of the output is also gentle.

At time T24, the node voltage V25 starts rising from 0 (Low) to V25_MAX (High). At time T27, the node voltage V25 reaches V25_MAX (High). After the elapse of a predetermined time, at time T30, the node voltage V25 starts falling from High to Low. In this case, the node voltage 25 is influenced by the gentle temporal change (gradient) of the node voltage of the input, and its gradient is gentle.

At time T25, the node voltage V26 starts falling from V26_MAX (High) to 0 (Low). At time T26, the node voltage V26 reaches 0. After the elapse of a predetermined time, at time T31, the node voltage V26 starts rising from Low to High.

The rising and the falling gradients of the node voltage V26 are steep. The reason for this is that the fan-out number of the inverter G33 is 1. In this case, while the node voltage V25 is influenced by the temporal change (gradient) of the node voltage 24, the node voltage V26 is not influenced, and has the same temporal change (gradient) as that of the node voltage V24. The same goes for the subsequent configuration.

That is, the first fan-out number of the first logic gate in each logic gate group is larger than the second fan-out number of the second and third logic gates. The first to third logic gates are set to have the same driving force as one another. In the configuration, the oscillator circuit 202 has high sensitivity to the HCI deterioration for each switching operation (in a time domain B). By the use of the oscillator circuit 202 in the configuration, the HCI deterioration of the transistor configuring the logic circuit 100 can be detected with high sensitivity.

Note that a system according to a related-art example is a system made of a combination of an inverter with a large driving force and an inverter with a small driving force. However, the logic gates (inverters) of the oscillator circuit 202 according to the first embodiment are set to have the same driving force, and thus, the power consumption is small. Therefore, the HCI deterioration of the semiconductor element can be accurately detected while the power consumption is reduced.

The oscillator circuit 202 further includes a selector SEL. The output of the selector SEL is connected to one input of the NAND gate 10. The selector SEL switches and outputs an input in response to a control signal SL when receiving the output of the logic gate group R32 and the output of the logic gate group R3m.

When the selector SEL selects the logic gate group R3m, the oscillator circuit 202 oscillates by use of the NAND gate 10 and the logic gate groups R31 to R3m. The number of logic gates used for oscillation provided when the selector SEL selects the logic gate group R32 is smaller than the number thereof provided when the selector SEL selects the logic gate group R3m. The oscillation cycle of the ring oscillator circuit is defined by a delay time of each oscillating logic gate and the number of levels of the oscillating logic gate. Thus, when the selector SEL selects the logic gate group R32, the total delay time is short, and the oscillator circuit oscillates fast. Therefore, the number of times of switching per unit time of each inverter increases, and thus, the smaller the number of logic gates used for oscillation is, the higher the sensitivity of the oscillator circuit 204 to the HCI deterioration is.

The HCI deterioration of each inverter configuring the oscillator circuit 202 varies even among the inverters with the same driving force from one another. Thus, in the detection of the HCI deterioration in the oscillator circuit 202, the larger the number of inverters used for oscillation is, the smaller the influence of the HCI deterioration variation among the inverters in the oscillator circuit 202 can be. Thus, in the detection of the HCI deterioration in the oscillator circuit 202, the selector SEL selects the logic gate group R3m, and uses all the logic gates configuring the oscillator circuit 202 for the oscillation.

In an oscillator circuit configured to adjust the number of levels in the oscillation, a stress applying mode and an HCI deterioration detecting mode can be switched. Specifically, the selector SEL performs the switch between the stress applying mode and the HCI deterioration detecting mode in response to the control signal SL.

The stress applying mode is a mode of enhancing sensitivity to the HCI deterioration by the less-leveled oscillation. The HCI deterioration detecting mode is a mode of detecting the HCI deterioration while suppressing the influence of variations in the HCI deterioration by the more-leveled oscillation.

Note that the numbers of NAND gates connected to the logic gate groups R31 to R3m in parallel may be the same or different.

The 4-input NAND gates NAD0 to NADn have been described as an example. However, the NAND gates are not limited to 4-input NAND gates, and may be 2-input or 3-input NAND gates. Further, not the NAND gate but a NOR gate, one input terminal of which is connected to the power supply voltage VDD, may employed.

For example, the HCI deterioration of the transistor configuring the logic circuit 100 can be detected with high sensitivity by use of the oscillator circuit 202 in the configuration. To the contrary, the deterioration of the semiconductor element may be influenced by not only the HCI but also bias temperature instability (BTI).

### SECOND EMBODIMENT

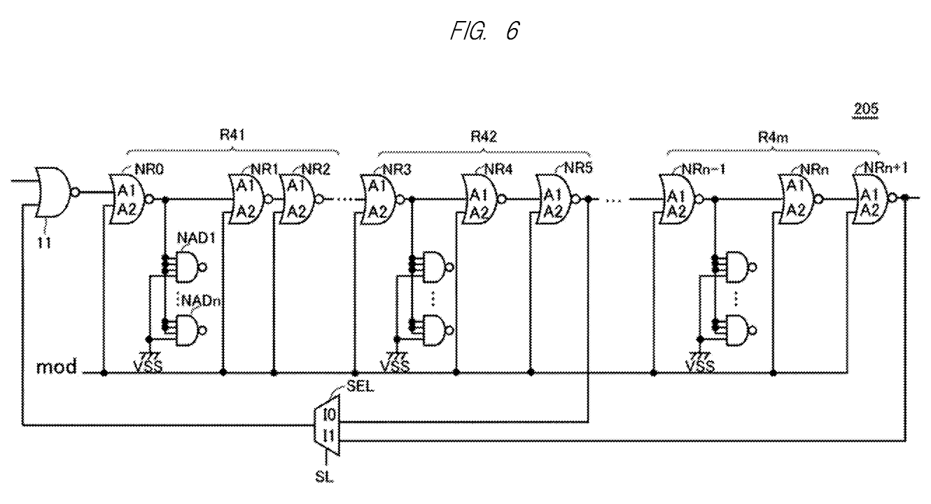

FIG. 6 is a diagram illustrating an exemplary configuration of an oscillator circuit 205 according to a second embodiment. With reference to FIG. 6, the oscillator circuit 205 includes a plurality of logic gate groups. Specifically, the oscillator circuit 205 includes a NOR gate 11 and logic gate groups R41 to R4m. The NOR gate 11 and the logic gate groups R41 to R4m are connected in series. The logic gate groups R41 to R4m includes first to third logic gates made of transistors and connected in series, respectively. The first fan-out number of the first logic gate is larger than the second fan-out number of the second and third logic gates, and the first to third logic gates are set to have the same driving force as one another.

In the present example, the logic gate group R41 includes NOR gates NR with the same driving force. The NOR gate NR1 and 4-input NAND gates, the number of which is “n”, are connected in parallel. Specifically, the NOR gate NR1 and the 4-input NAND gates, the number of which is “n”, are connected in parallel as similar to the description in FIG. 3.

The outputs of the 4-input NAND gates NAD1 to NADn are open. These NAND gates are connected in parallel in order to increase the total capacity of the output of the NOR gate NR0. Thus, the outputs of these NAND gates may be open or may be connected to the NOR gate NR2 arranged at their post level.

The fan-out number of the NOR gate NR0 is “n + 1”. The fan-out number of the NOR gate NR1 is 1. The fan-out number of the NOR gate NR2 is 1.

The configurations of the other logic gate groups R42 to R4m are similar to that of the logic gate group R41, and thus, will not be repeatedly described in detail.

Thus, as similar to the oscillator circuit 202 according to the first embodiment, in the oscillator circuit 205 according to the second embodiment, the first fan-out number of the first logic gate in each logic gate group is larger than the second fan-out number of the second and third logic gates. The first to third logic gates are set to have the same driving force as one another. In the configuration, the oscillator circuit 205 has high sensitivity to the HCI deterioration for each switching operation (in the time domain B). By the use of the oscillator circuit 205 in the configuration, the HCI deterioration of the transistor configuring the logic circuit 100 can be detected with high sensitivity.

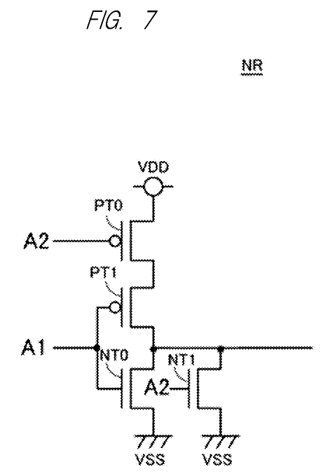

FIG. 7 is a diagram for explaining the NOR gate NR according to the first embodiment. FIG. 7 illustrates a configuration of the NOR gate NR. The NOR gate NR includes P-channel MOS transistors PT0 and PT1 and N-channel MOS transistors NT0 and NT1. The P-channel MOS transistors PT0 and PT1 are connected in series between the power supply voltage VDD and the output node. The N-channel MOS transistors NT0 and NT1 are connected in parallel between the output node and the fixed voltage VSS. The P-channel MOS transistor PT0 and the N-channel MOS transistor NT1 are connected to a node A2. The P-channel MOS transistor PT1 and the N-channel MOS transistor NT0 are connected to a node A1.

In the present example, the node A2 receives a control signal “mod” as its input. The control signal mod is set to “0” (“L” level) during the operation of the oscillator circuit (during oscillation), and is set to “1” (“H” level) during no operation of the oscillator circuit (during no oscillation). The control signal mod is output from the control circuit 500. When the control signal mod is “1,” the P-channel MOS transistor PT1 is set to the electrical disconnection state. The transistors for the switching operation are the P-channel MOS transistor PT1 and the N-channel MOS transistor NT0. The P-channel MOS transistor PT0 is in the electrical disconnection state during no oscillation of the oscillator circuit 205, and therefore, the voltage between the source and the gate of the P-channel MOS transistor PT1 is much smaller than the power supply voltage VDD. Thus, the influence of the bias temperature instability (BTI) on the P-channel MOS transistor PT1 can be suppressed. When the control signal mod is “1,” the output signal of the NOR gate NR is “0” and is connected to the node A1 of its next NOR gate, and therefore, there is no influence of BTI on the N-channel MOS transistor NT0.

Therefore, the HCI deterioration can be accurately detected by the oscillator circuit 205 according to the second embodiment of the present disclosure while the influence of BTI deterioration on the P-channel MOS transistor is particularly suppressed.

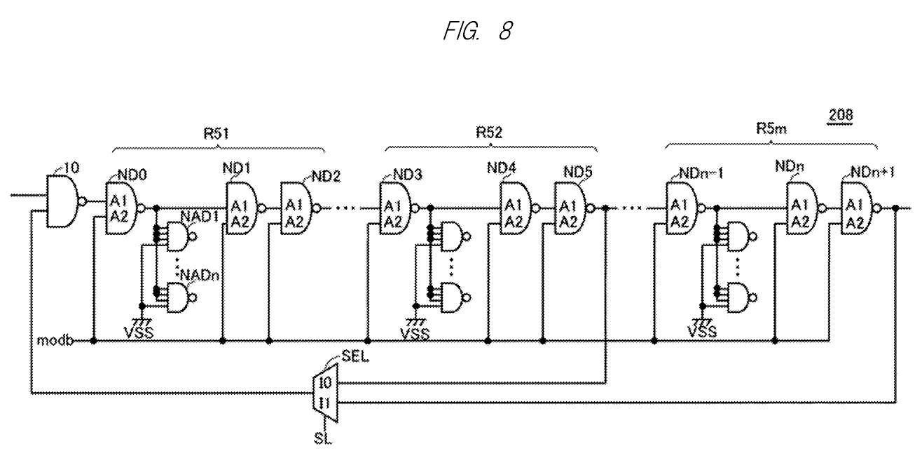

FIG. 8 is a diagram illustrating an exemplary configuration of an oscillator circuit 208 according to a modification example of the second embodiment. With reference to FIG. 8, the oscillator circuit 208 includes a plurality of logic gate groups. Specifically, the oscillator circuit 208 includes the NAND gate 10 and logic gate groups R51 to R5m. The NAND gate 10 and the logic gate groups R51 to R5m are connected in series. The logic gate groups R51 to R5m includes first to third logic gates made of transistors and connected in series, respectively. The first fan-out number of the first logic gate is larger than the second fan-out number of the second and third logic gates, and the first to third logic gates are set to have the same driving force.

In the present modification example, each of the logic gate groups R51 to R5m includes NAND gates ND with the same driving force. The NAND gate ND1 and the 4-input NAND gates, the number of which is “n”, are connected in parallel.

The outputs of the 4-input NAND gates NAD1 to NADn configuring the logic gate group R51 are open. These NAND gates are connected in parallel in order to increase the total capacity of the output of the NAND gate ND0. Thus, the outputs of these NAND gates may be open or may be connected to the NAND gate ND2 arranged at their post level.

The fan-out number of the NAND gate ND0 is “n + 1”. The fan-out number of the NAND gate ND1 is 1. The fan-out number of the NAND gate ND2 is 1.

The configurations of the other logic gate groups R52 to R5m are similar to that of the logic gate group R51, and thus, will not be repeatedly described in detail.

Thus, as similar to the oscillator circuit 205 according to the second embodiment, in the oscillator circuit 208 according to the modification example of the second embodiment, the first fan-out number of the first logic gate in each logic gate group is larger than the second fan-out number of the second and third logic gates. The first to third logic gates are set to have the same driving force as one another. In the configuration, the oscillator circuit 208 has high sensitivity to the HCI deterioration for each switching operation (in the time domain B). By the use of the oscillator circuit 208 in the configuration, the HCI deterioration of the transistor configuring the logic circuit 100 can be detected with high sensitivity.

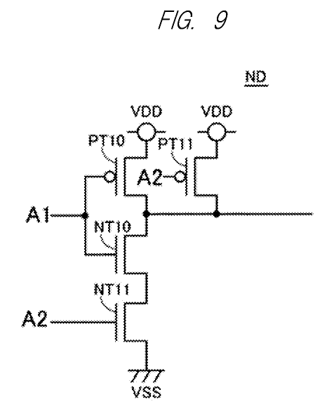

FIG. 9 is a diagram for explaining the NAND gate ND according to the modification example of the second embodiment. With reference to FIG. 9, the NAND gate ND includes P-channel MOS transistors PT10 and PT11 and N-channel MOS transistors NT10 and NT11. The P-channel MOS transistors PT10 and PT11 are connected in parallel between the power supply voltage VDD and the output node. The N-channel MOS transistors NT10 and NT11 are connected in series between the output node and the fixed voltage VSS. The P-channel MOS transistor PT10 and the N-channel MOS transistor NT10 are connected to the node A1. The P-channel MOS transistor PT11 and the N-channel MOS transistor NT11 are connected to the node A2.

In the present example, the node A2 receives a control signal “modb” as its input. The control signal modb is an inverted signal of the control signal mod, and is set to “1” (“H” level) during the operation of the oscillator circuit (during oscillation), and is set to “0” (“L” level) during no operation of the oscillator circuit (during no oscillation). The control signal modb is output from the control circuit 500. When the control signal modb is “0,” the N-channel MOS transistor NT11 is set to the electrical disconnection state. When the control signal modb is “1,” the N-channel MOS transistor NT11 is set to the electrical connection state. The transistors for the switching operation are the P-channel MOS transistor PT10 and the N-channel MOS transistor NT10. The control signal modb is “0” while the N-channel MOS transistor NT11 of the NAND gate ND is in the electrical disconnection state during no oscillation of the oscillator circuit 208, and therefore, the voltage between the source and the gate of the N-channel MOS transistor NT10 is much smaller than the power supply voltage VDD. Thus, the influence of the bias temperature instability (BTI) on the N-channel MOS transistor NT10 can be suppressed. When the control signal modb is “0,” the output signal of the NAND gate ND is “1” and is connected to the node A1 of its next NAND gate, and therefore, there is no influence of BTI on the P-channel MOS transistor PT10.

Therefore, the HCI deterioration can be accurately detected by the oscillator circuit 208 according to the modification example of the second embodiment of the present disclosure while the influence of BTI deterioration on the N-channel MOS transistor is particularly suppressed.

### THIRD EMBODIMENT

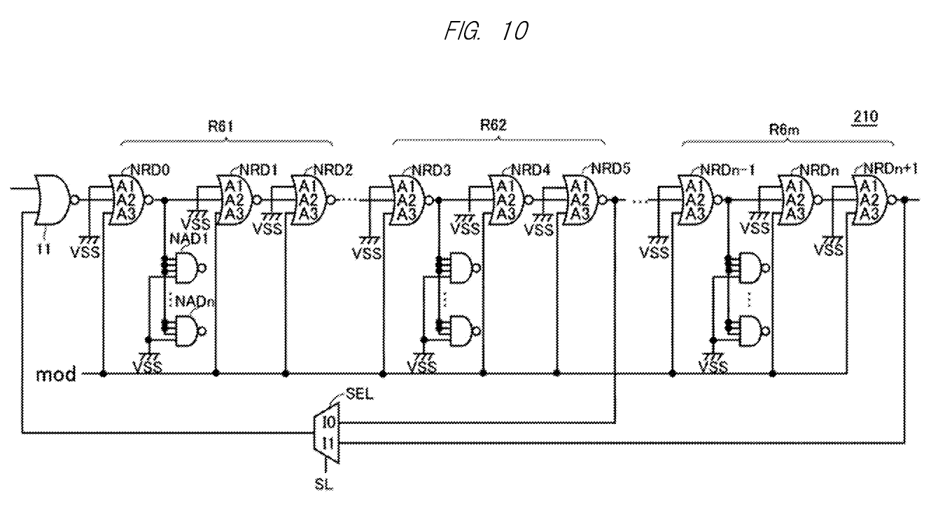

FIG. 10 is a diagram illustrating an exemplary configuration of an oscillator circuit 210 according to a third embodiment. With reference to FIG. 10, the oscillator circuit 210 includes a plurality of logic gate groups. Specifically, the oscillator circuit 210 includes the NOR gate 11 and logic gate groups R61 to R6m. The NOR gate 11 and the logic gate groups R61 to R6m are connected in series. The logic gate groups R61 to R6m includes first to third logic gates made of transistors and connected in series, respectively. The first fan-out number of the first logic gate is larger than the second fan-out number of the second and third logic gates, and the first to third logic gates are set to have the same driving force as one another.

In the present example, the logic gate group R61 includes NOR gates NRD with the same driving force. The NOR gate NRD1 and 4-input NAND gates, the number of which is “n”, are connected in parallel. The outputs of the 4-input NAND gates NAD1 to NADn are open. These NAND gates are connected in parallel in order to increase the total capacity of the output of the NOR gate NRD0. Thus, the outputs of these NAND gates may be open or may be connected to the NOR gate NRD2 arranged at their post level.

The fan-out number of the NOR gate NRD0 is “n + 1”. The fan-out number of the NOR gate NRD1 is 1. The fan-out number of the NOR gate NRD2 is 1.

The configurations of the other logic gate groups R62 to R6m are similar to that of the logic gate group R61, and thus, will not be repeatedly described in detail.

Thus, as similar to the oscillator circuit 202 according to the first embodiment, in the oscillator circuit 210 according to the third embodiment, the first fan-out number of the first logic gate in each logic gate group is larger than the second fan-out number of the second and third logic gates. The first to third logic gates are set to have the same driving force as one another. In the configuration, the oscillator circuit 210 has high sensitivity to the HCI deterioration for each switching operation (in the time domain B). By the use of the oscillator circuit 210 in the configuration, the HCI deterioration of the transistor configuring the logic circuit 100 can be detected with high sensitivity.

FIG. 11 is a diagram for explaining the NOR gate NRD according to the third embodiment. With reference to FIG. 11, the NOR gate NRD includes P-channel MOS transistors PT0 to PT3 and N-channel MOS transistors NT0 to NT3. The P-channel MOS transistors PT0 to PT2 are connected in series between the power supply voltage VDD and the output node. The N-channel MOS transistors NT0 to NT2 are connected in parallel between the output node and the fixed voltage VSS. The P-channel MOS transistor PT0 and the N-channel MOS transistor NT2 are connected to a node A3. The P-channel MOS transistor PT1 and the N-channel MOS transistor NT1 are connected to the node A2. The P-channel MOS transistor PT2 and the N-channel MOS transistor NT0 are connected to the node A1.

In the present example, the node A1 is connected to the fixed voltage VSS. The node A2 receives an output signal as its input from the NOR gate arranged at its previous level. The node A3 receives the control signal “mod” as its input. The control signal mod is set to “0” (“L” level) during the operation of the oscillator circuit (during oscillation), and is set to “1” (“H” level) during no operation of the oscillator circuit (during no oscillation). The control signal mod is output from the control circuit 500. When the control signal mod is “1,” the P-channel MOS transistor PT0 is set to the electrical disconnection state. When the control signal mod is “0,” the P-channel MOS transistor PT0 is set to the electrical connection state. The transistors for the switching operation are the P-channel MOS transistor PT1 and the N-channel MOS transistor NT1. The control signal mod is “1” while the P-channel MOS transistor PT0 of the NOR gate NRD is in the electrical disconnection state during no oscillation of the oscillator circuit 210, and therefore, the voltage between the source and the gate of the P-channel MOS transistor PT1 is much smaller than the power supply voltage VDD. Thus, the influence of the bias temperature instability (BTI) on the P-channel MOS transistor PT1 can be suppressed. When the control signal mod is “1,” the output signal of the NOR gate NRD is “0” and is connected to the node A1 of its next NOR gate, and therefore, there is no influence of BTI on the N-channel MOS transistor NT0.

Therefore, the HCI deterioration can be accurately detected by the oscillator circuit 210 according to the third embodiment of the present disclosure while the influence of BTI deterioration is suppressed.

The P-channel MOS transistor PT1 for the switching operation is connected to the output node via the P-channel MOS transistor PT2. By the configuration, the HCI deterioration of the P-channel MOS transistor PT1 can be suppressed.

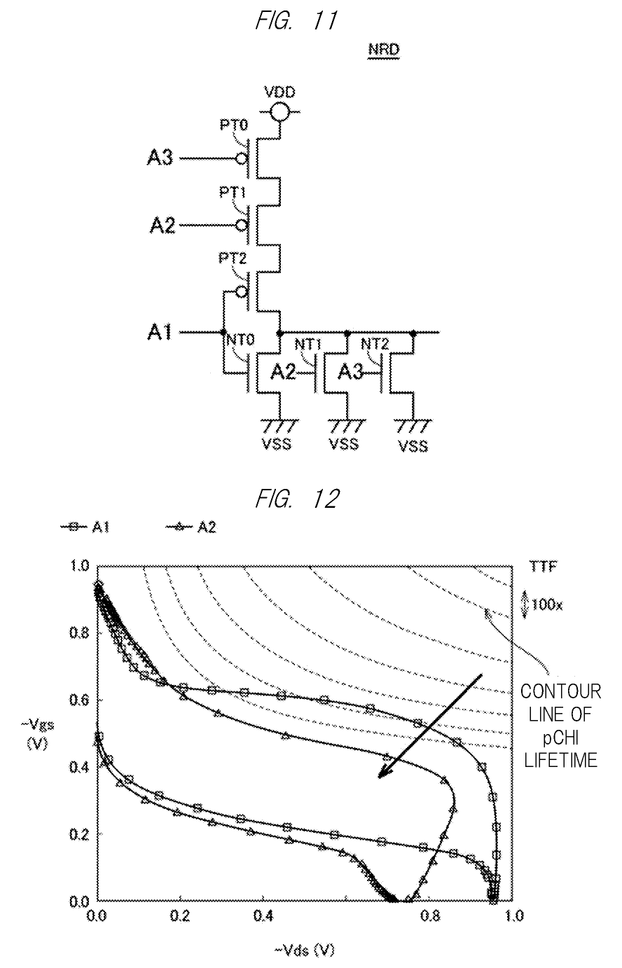

FIG. 12 is a diagram for explaining difference in lifetime due to HCI between the P-channel MOS transistors PT1 and PT2. FIG. 12 illustrates a case in which the P-channel MOS transistor PT2 is selected and a case in which the P-channel MOS transistor PT1 is selected as the transistor for the switching operation. The drawing illustrates a contour line “pHCI” indicating the lifetime of the P-channel MOS transistor due to HCI. This shows that a transistor with a smaller source-drain volage has a longer lifetime. That is, the effect of suppressing the HCI deterioration is higher in the case of the signal input from the NOR gate arranged at its previous level to the node A2 as the gate of the P-channel MOS transistor PT1 than the case of the signal input from the NOR gate arranged at its previous level to the node A1 as the gate of the P-channel MOS transistor PT2.

In the detection of the HCI deterioration by the oscillator circuit 210 according to the third embodiment of the present disclosure, the influence of HCI deterioration on the P-channel MOS transistor is particularly suppressed. Thereby, the HCI deterioration of the N-channel MOS transistor can be accurately detected.

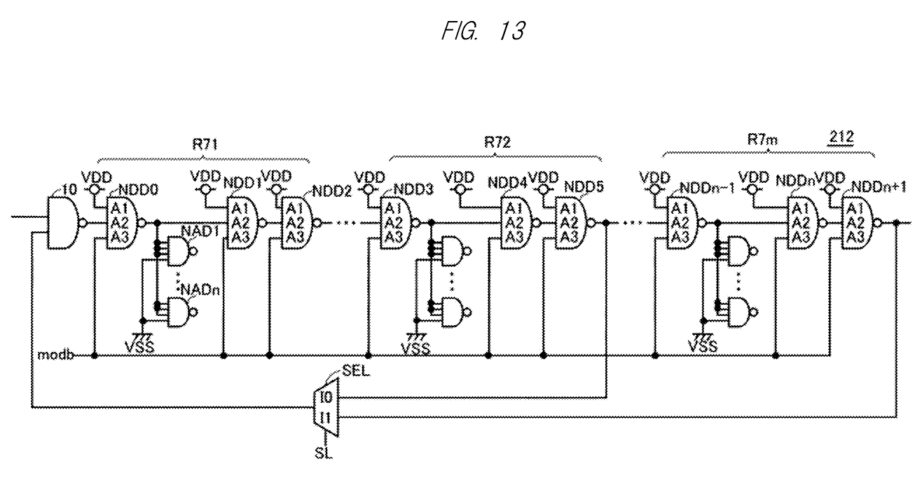

FIG. 13 is a diagram illustrating an exemplary configuration of an oscillator circuit 212 according to a modification example of the third embodiment. With reference to FIG. 13, the oscillator circuit 212 includes a plurality of logic gate groups. Specifically, the oscillator circuit 212 includes the NAND gate 10 and logic gate groups R71 to R7m. The NAND gate 10 and the logic gate groups R71 to R7m are connected in series. The logic gate groups R71 to R7m include first to third logic gates made of transistors and connected in series, respectively. The first fan-out number of the first logic gate is larger than the second fan-out number of the second and third logic gates, and the first to third logic gates are set to have the same driving force as one another.

In the present example, the logic gate group R71 includes NAND gates NDD with the same driving force. The NAND gate NDD1 and 4-input NAND gates, the number of which is “n”, are connected in parallel.

The outputs of the 4-input NAND gates NAD1 to NADn are open. These NAND gates are connected in parallel in order to increase the total capacity of the output of the NAND gate NDD0. Thus, the outputs of these NAND gates may be open or may be connected to the NAND gate NDD2 arranged at their post level.

The fan-out number of the NAND gate NDD0 is “n + 1”. The fan-out number of the NAND gate NDD1 is 1. The fan-out number of the NAND gate NDD2 is 1.

The configurations of the other logic gate groups R72 to R7m are similar to that of the logic gate group R71, and thus, will not be repeatedly described in detail.

Thus, as similar to the oscillator circuit 202 according to the first embodiment, in the oscillator circuit 212 according to the modification example of the third embodiment, the first fan-out number of the first logic gate in each logic gate group is larger than the second fan-out number of the second and third logic gates. The first to third logic gates are set to have the same driving force as one another. In the configuration, the oscillator circuit 212 has high sensitivity to the HCI deterioration for each switching operation (in the time domain B). By the use of the oscillator circuit 212 in the configuration, the HCI deterioration of the transistor configuring the logic circuit 100 can be detected with high sensitivity.

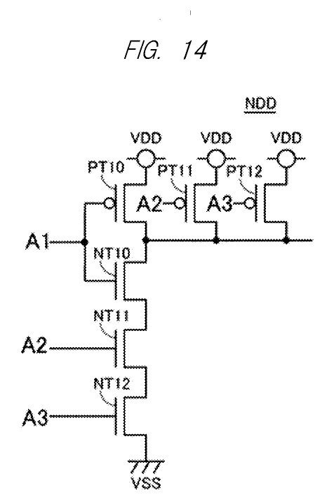

FIG. 14 is a diagram for explaining the NAND gate NDD according to the modification example of the third embodiment. With reference to FIG. 14, the NAND gate NDD includes P-channel MOS transistors PT10 to PT12 and N-channel MOS transistors NT10 to NT12. The P-channel MOS transistors PT10 to PT12 are connected in parallel between the power supply voltage VDD and the output node. The N-channel MOS transistors NT10 to NT12 are connected in series between the output node and the fixed voltage VSS. The P-channel MOS transistor PT10 and the N-channel MOS transistor NT10 are connected to the node A1. The P-channel MOS transistor PT11 and the N-channel MOS transistor NT11 are connected to the node A2. The P-channel MOS transistor PT12 and the N-channel MOS transistor NT12 are connected to the node A3.

In the present example, the node A1 is connected to the power supply voltage VDD. The node A2 receives an output signal as its input from the NAND gate arranged at its previous level. The node A3 receives the control signal “modb” as its input. The control signal modb is set to “1” (“H” level) during the operation of the oscillator circuit (during oscillation), and is set to “0” (“L” level) during no operation of the oscillator circuit (during no oscillation). The control signal modb is output from the control circuit 500. When the control signal modb is “0,” the N-channel MOS transistor NT12 is set to the electrical disconnection state. When the control signal modb is “1,” the N-channel MOS transistor NT12 is set to the electrical connection state. The transistors for the switching operation are the N-channel MOS transistor NT11 and the P-channel MOS transistor PT11. The control signal modb is “0” while the N-channel MOS transistor NT12 of the NAND gate NDD is in the electrical disconnection state during no oscillation of the oscillator circuit 212, and therefore, the voltage between the source and the gate of the N-channel MOS transistor NT11 is much smaller than the power supply voltage VDD. Thus, the influence of the bias temperature instability (BTI) on the N-channel MOS transistor NT11 can be suppressed. When the control signal modb is “0,” the output signal of the NAND gate NDD is “1” and is connected to the node A1 of its next NAND gate, and therefore, there is no influence of BTI on the P-channel MOS transistor PT10.

The HCI deterioration can be accurately detected by the oscillator circuit 212 according to the modification example of the third embodiment of the present disclosure while the influence of BTI deterioration is suppressed.

The N-channel MOS transistor NT11 for the switching operation is connected to the output node via the N-channel MOS transistor NT10. By the configuration, the source-drain voltage can be decreased as similar to the description in FIG. 12, and the HCI deterioration of the N-channel MOS transistor NT11 can be suppressed.

In the detection of the HCI deterioration by the oscillator circuit 212 according to the modification example of the third embodiment of the present disclosure, the influence of HCI deterioration on the N-channel MOS transistor is particularly suppressed. Thereby, the HCI deterioration of the P-channel MOS transistor can be accurately detected.

By the use of the oscillator circuit in the configuration, the HCI deterioration can be detected while the P-channel MOS transistors and the N-channel MOS transistors are separated.

The 3-input NAND gates or NOR gates have been described above as the example. However, the above description is similarly applicable to 4-input NAND gates or NOR gates.

### FOURTH EMBODIMENT

In a fourth embodiment, a system for further accurately detecting the HCI deterioration by combination of various oscillator circuits will be described.

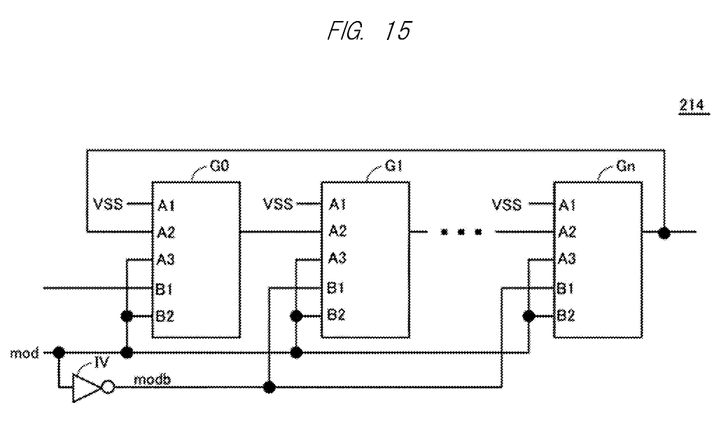

FIG. 15 is a diagram illustrating an exemplary configuration of an oscillator circuit 214 according to the fourth embodiment. With reference to FIG. 15, the oscillator circuit 214 includes an inverter IV and complex gates G0 to Gn. The complex gates G0 to Gn are connected in series such that the output of the complex gate Gn arranged at the final level is fed back to the complex gate G0 arranged at the first level.

FIG. 16 is a diagram for explaining a circuit configuration of the complex gate G (during no oscillation) according to the fourth embodiment. With reference to FIG. 16, the complex gate G includes P-channel MOS transistors PT20 to PT22 and N-channel MOS transistors NT20 to NT22. The P-channel MOS transistors PT20 to PT22 are connected in series between the power supply voltage VDD and the output node. The N-channel MOS transistors NT20 and NT21 are connected in series between the output node and the fixed voltage VSS. The N-channel MOS transistor NT22 is connected in parallel with the N-channel MOS transistors NT20 and NT21 as well as being between the fixed voltage VSS and the output node.

The P-channel MOS transistor PT21 and the N-channel MOS transistor NT21 are connected to the node A2. The P-channel MOS transistor PT22 is connected to the node A1. The P-channel MOS transistor PT20 is connected to the node A3. The N-channel MOS transistor NT20 is connected to the node B1. The N-channel MOS transistor NT22 is connected to the node B2.

In the present example, the node A1 is connected to the fixed voltage VSS during oscillation and no oscillation. The node A2 receives an output signal as its input from the NOR gate arranged at its previous level. The nodes A3 and B2 receive the control signal mod as their input. The node B1 of the complex gate G arranged at the first level receives a signal as its input from the outside. The nodes B1 of the complex gates G1 to Gn arranged at the second to subsequent levels receive the inverted control signal modb that is the inverted signal of the control signal mod as their input, via the inverter IV.

The control signal mod is set to “0” (“L” level) during the operation of the oscillator circuit (during oscillation), and is set to “1” (“H” level) during no operation of the oscillator circuit (during no oscillation). The inverted control signal modb is set to “1” (“H” level) during the operation of the oscillator circuit (during oscillation), and is set to “0” (“L” level) during no operation of the oscillator circuit (during no oscillation). The control signal mod is output from the control circuit 500.

The P-channel MOS transistor PT20 is in the electrical disconnection state during no oscillation of the oscillator circuit 214, and therefore, the voltage between the source and the gate of the P-channel MOS transistor PT21 is much smaller than the power supply voltage VDD. Thus, the influence of the bias temperature instability (BTI) on the P-channel MOS transistor PT21 can be suppressed.

The voltage between the source and the drain of the P-channel MOS transistor PT21 is very small. Thus, the HCI deterioration of the P-channel MOS transistor PT21 can be suppressed.

The N-channel MOS transistor NT21 is in the electrical disconnection state during no oscillation of the oscillator circuit 214, and therefore, the voltage between the source and the gate of the N-channel MOS transistor NT20 is much smaller than the power supply voltage VDD. Thus, the influence of the bias temperature instability (BTI) on the N-channel MOS transistor NT20 can be suppressed.

The voltage between the source and the drain of the N-channel MOS transistor NT21 is also very small. Thus, the HCI deterioration of the N-channel MOS transistor NT21 can also be suppressed.

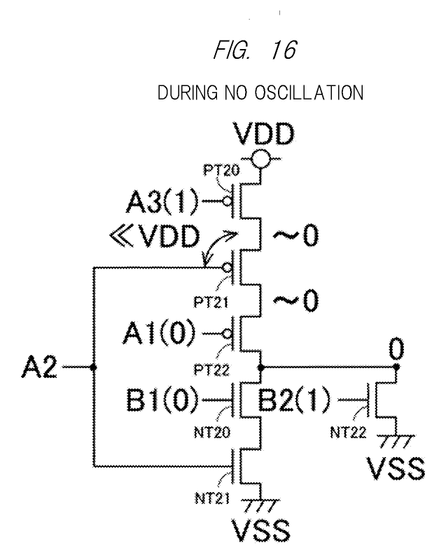

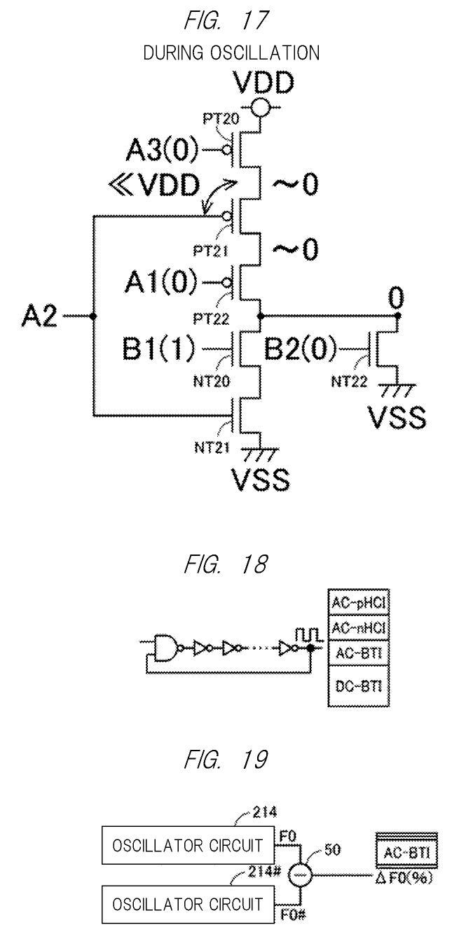

FIG. 17 is a diagram for explaining a circuit configuration of the complex gate G (during oscillation) according to the fourth embodiment. With reference to FIG. 17, in the present example, the node A1 is connected to the fixed voltage VSS during oscillation and no oscillation. The node A2 receives an output signal as its input from the NOR gate arranged at its previous level. The nodes A3 and B2 receive the control signal mod as their input. The node B1 of the complex gate G arranged at the first level receives a signal as its input from the outside. The nodes B1 of the complex gates G1 to Gn arranged at the second to subsequent levels receive the inverted control signal modb that is the inverted signal of the control signal mod as their input, via the inverter IV.

During the oscillation of the oscillator circuit 214, the control signal mod is “0” while the P-channel MOS transistor PT20 of the complex gate G is in the electrical connection state. The N-channel MOS transistor NT22 is in the electrical disconnection state. The P-channel MOS transistor PT22 and the N-channel MOS transistor NT20 are set to the electrical connection state.

The P-channel MOS transistor PT21 for the switching operation is connected to the output node via the P-channel MOS transistor PT22. The N-channel MOS transistor NT21 is connected to the output node via the N-channel MOS transistor NT20. In the configuration, the HCI deteriorations of the P-channel MOS transistor PT21 and the N-channel MOS transistor NT21 can be suppressed. That is, in the oscillator circuit 214 according to the fourth embodiment, both the BTI deterioration and the HCI deterioration of the P-channel MOS transistor and the N-channel MOS transistor can be suppressed.

FIG. 18 is a diagram for explaining causes of a frequency shift of an oscillator circuit according to a comparative example. With reference to FIG. 18, deterioration factors of the semiconductor element becoming the causes of the frequency shift of the oscillator circuit according to the comparative example will be described. The HCI deterioration (AC-pHCI) on the P-channel MOS transistor during oscillation, the HCI deterioration (AC-nHCI) on the N-channel MOS transistor during oscillation, the bias temperature instability (BTI) deterioration (AC-BTI) during oscillation, and the BTI deterioration (DC-BTI) during no oscillation are exemplified here.

FIG. 19 is a diagram for explaining causes of a frequency shift of the oscillator circuit 214 according to the fourth embodiment. FIG. 19 illustrates a case with oscillator circuits 214, 214# and a computer circuit 50. As described above, the oscillator circuit 214 is an oscillator circuit that can suppress the HCI deterioration and the BTI deterioration of the P-channel MOS transistor and the N-channel MOS transistor even during the oscillation. The oscillator circuit 214# is a circuit that is the same as the oscillator circuit 214 but does not oscillate. Note that the value of the frequency at the initial operation of the oscillator circuit 214 instead of the oscillator circuit 214# may be stored.

The computer circuit 50 calculates a frequency fluctuation rate ΔF0 based on a difference between a frequency F0 output from the oscillator circuit 214 and a frequency F0# output from the oscillator circuit 214#. The frequency fluctuation rate ΔF0 corresponds to the frequency shift based on the bias temperature instability (BTI) deterioration (AC-BTI) during oscillation. Specifically, the computer circuit 50 calculates ΔF0 from “1 - F0/F0#.”

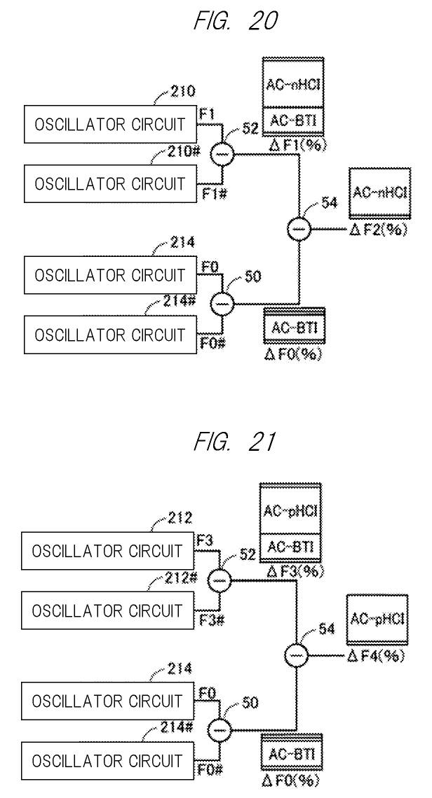

FIG. 20 is a diagram for explaining a system for detecting the HCI deterioration based on a combination of oscillator circuits according to the fourth embodiment. FIG. 20 illustrates a case with oscillator circuits 210, 210#, oscillator circuits 214, 214#, and computer circuits 50, 52, 54.

The oscillator circuit 210 is an oscillator circuit that can suppress the HCI deterioration and the BTI deterioration of the P-channel MOS transistor during oscillation. The oscillator circuit 210# is a circuit that is the same as the oscillator circuit 210 but does not oscillate. Note that the value of the frequency at the initial operation of the oscillator circuit 210 instead of the oscillator circuit 210# may be stored.

The computer circuit 52 calculates a frequency fluctuation rate ΔF1 based on a difference between a frequency F1 output from the oscillator circuit 210 and a frequency F1# output from the oscillator circuit 210#. The frequency fluctuation rate ΔF1 corresponds to the frequency shift based on the HCI deterioration (AC-nHCI) and the bias temperature instability (BTI) deterioration (AC-BTI) of the N-channel MOS transistor during oscillation. Specifically, the computer circuit 52 calculates ΔF1 from “1 – F1/F1#.”

As described above, the oscillator circuit 214 is a circuit that can suppress the HCI deterioration and the BTI deterioration even during oscillation. The oscillator circuit 214# is a circuit that is the same as the oscillator circuit 214 but does not oscillate. Note that the value of the frequency at the initial operation of the oscillator circuit 214 instead of the oscillator circuit 214# may be stored.

The computer circuit 50 calculates the frequency fluctuation rate ΔF0 based on the difference between the frequency F0 output from the oscillator circuit 214 and the frequency F0# output from the oscillator circuit 214#. The frequency fluctuation rate ΔF0 corresponds to the frequency shift based on the bias temperature instability (BTI) deterioration (AC-BTI) during oscillation. Specifically, the computer circuit 50 calculates ΔF0 from “1 – F0/F0#.”

Thus, the computer circuit 54 outputs a frequency fluctuation rate ΔF2 based on the difference between an output from the computer circuit 52 and an output from the computer circuit 50. The frequency fluctuation rate ΔF2 corresponds to the frequency shift due to the HCI deterioration (AC-nHCI) of the N-channel MOS transistor.

That is, by the combination of various oscillator circuits, the HCI deterioration of the N-channel MOS transistor during oscillation can be particularly detected. For example, by the use of the oscillator circuit in the configuration, the HCI deterioration of the N-channel MOS transistor configuring the logic circuit 100 can be detected with high sensitivity.

FIG. 21 is a diagram for explaining a system for detecting the HCI deterioration based on a combination of the oscillator circuits according to the modification example of the fourth embodiment. FIG. 21 illustrates a case with the oscillator circuits 212, 212#, the oscillator circuits 214, 214#, and the computer circuits 50, 52, 54.

The oscillator circuit 212 is an oscillator circuit that can suppress the HCI deterioration and the BTI deterioration of the P-channel MOS transistor during oscillation. The oscillator circuit 212# is a circuit that is the same as the oscillator circuit 212 but does not oscillate. Note that the value of the frequency at the initial operation of the oscillator circuit 212 instead of the oscillator circuit 212# may be stored.

The computer circuit 52 calculates a frequency fluctuation rate ΔF3 based on a difference between a frequency F3 output from the oscillator circuit 212 and a frequency F3# output from the oscillator circuit 212#. The frequency fluctuation rate ΔF3 corresponds to the frequency shift based on the HCI deterioration (AC-pHCI) and the bias temperature instability (BTI) deterioration (AC-BTI) of the P-channel MOS transistor during oscillation. Specifically, the computer circuit 52 calculates ΔF3 from “1 – F3/F3#.”

As described above, the oscillator circuit 214 is an oscillator circuit that can suppress the HCI deterioration and the BTI deterioration even during oscillation. The oscillator circuit 214# is a circuit that is the same as the oscillator circuit 214 but does not oscillate. Note that the value of the frequency at the initial operation of the oscillator circuit 214 instead of the oscillator circuit 214# may be stored.

The computer circuit 50 calculates the frequency fluctuation rate ΔF0 based on a difference between the frequency F0 output from the oscillator circuit 214 and the frequency F0# output from the oscillator circuit 214#. The frequency fluctuation rate ΔF0 corresponds to the frequency shift based on the bias temperature instability (BTI) deterioration (AC-BTI) during oscillation. Specifically, the computer circuit 50 calculates ΔF0 from “1 – F0/F0#.”

Thus, the computer circuit 54 outputs a frequency fluctuation rate ΔF4 based on a difference between an output from the computer circuit 52 and an output from the computer circuit 50. The frequency fluctuation rate ΔF4 corresponds to the frequency shift due to the HCI deterioration (AC-pHCI) of the P-channel MOS transistor.

That is, by the combination of various oscillator circuits, the HCI deterioration of the P-channel MOS transistor during oscillation can be particularly detected. For example, by the use of the oscillator circuit in the configuration, the HCI deterioration of the P-channel MOS transistor configuring the logic circuit 100 can be detected with high sensitivity.

In the system according to the fourth embodiment, the HCI deterioration of the semiconductor element can be accurately detected while the P-channel MOS transistor and the N-channel MOS transistor are separated.

In the foregoing, the present disclosure has been concretely described based on the embodiments. However, it is needless to say that the present disclosure is not limited to the foregoing embodiments, and various modifications can be made within the scope of the present disclosure.

What is claimed is:

1. A semiconductor device comprising:
an oscillator circuit including a plurality of logic gate groups connected in series;
a frequency counter measuring an oscillation frequency of the oscillator circuit; and
a comparator comparing a reference value and the oscillation frequency of the oscillator circuit measured by the frequency counter,
wherein each of the plurality of logic gate groups includes first to third logic gates each made of a transistor and connected in series,
wherein a first fan-out number of the first logic gate is larger than a second fan-out number of each of the second logic gate and the third logic gate, and
wherein a driving force of the first logic gate, a driving force of the second logic gate and a driving force of the third logic gate are same as one another.

2. The semiconductor device according to claim 1,
wherein the oscillator circuit includes a selector circuit changing the number of connection levels of the plurality of logic gate groups connected in series.

3. The semiconductor device according to claim 1,
wherein the reference value is an initial value counted by the frequency counter.

4. The semiconductor device according to claim 1, further comprising:
a dummy oscillator circuit having the same circuit configuration as a circuit configuration of the oscillator circuit that does not oscillate during normal time but oscillates during measurement,
wherein the reference value is an oscillation frequency of the dummy oscillator circuit measured by the frequency counter during the measurement.

5. The semiconductor device according to claim 1,
wherein each of the first to third logic gates includes:
a first transistor and a second transistor being connected in series via an output node between a first voltage and a second voltage, and being complementarily set to be in an electrical connection or electrical disconnection state during the oscillation of the oscillator circuit in response to an input signal;
a third transistor being connected between the first transistor and the first voltage, being set to be in the electrical connection state during the oscillation of the oscillator circuit or the electrical disconnection state during no oscillation of the oscillator circuit, and decreasing a voltage between a gate and a source of the first transistor; and
a fourth transistor being connected in parallel with the second transistor between the output node and the second voltage, and being set to be in the electrical connection state during no oscillation of the oscillator circuit.

6. The semiconductor device according to claim 5,
wherein each of the first to third logic gates further includes:
a fifth transistor being connected between the first transistor and the output node, and being set to be in the electrical connection state during the oscillation of the oscillator circuit.

7. A semiconductor device comprising:
a first oscillator circuit being capable of suppressing a deterioration of a transistor due to hot carrier injection by an oscillation;
a first frequency counter measuring an oscillation frequency of the first oscillator circuit;
a first computer circuit calculating a difference between a first reference value and the oscillation frequency of the first oscillator circuit measured by the first frequency counter;
a second oscillator circuit being capable of suppressing a deterioration of a transistor due to hot carrier injection by the oscillation;
a second frequency counter measuring an oscillation frequency of the second oscillator circuit;
a second computer circuit calculating a difference between a second reference value and the oscillation frequency of the second oscillator circuit measured by the second frequency counter; and
a detector circuit detecting the deterioration due to the hot carrier injection, based on the differences calculated by the first computer circuit and the second computer circuit.

8. The semiconductor device according to claim 7,
wherein the first oscillator circuit suppresses a deterioration of a P-channel transistor due to hot carrier injection.

9. The semiconductor device according to claim 7,
wherein the first oscillator circuit suppresses a deterioration of an N-channel transistor due to hot carrier injection.

10. The semiconductor device according to claim 7,
wherein the first reference value and the second reference value are initial values counted by the first frequency counter and the second frequency counter, respectively.

11. The semiconductor device according to claim 7, further comprising:
a first dummy oscillator circuit having the same circuit configuration as a circuit configuration of the first oscillator circuit that does not oscillate during normal time but oscillates during measurement; and
a second dummy oscillator circuit having the same circuit configuration as a circuit configuration of the second oscillator circuit that does not oscillate during the normal time but oscillates during the measurement,
wherein the first and second reference values are oscillation frequencies of the first and second dummy oscillator circuits measured by the first and second frequency counters, respectively, during the measurement.

12. The semiconductor device according to claim 7,
wherein the first oscillator circuit includes a plurality of logic gate groups connected in series,
wherein each of the plurality of logic gate groups includes first to third logic gates each made of a transistor and connected in series,
wherein a first fan-out number of the first logic gate is larger than a second fan-out number of the second logic gate and the third logic gate, and
wherein the first to third logic gates have the same driving force from one another.

13. The semiconductor device according to claim 12,
wherein each of the first to third logic gates includes:
a first transistor and a second transistor being connected in series via an output node between a first voltage and a second voltage, and being complementarily set to be in an electrical connection or electrical disconnection state during the oscillation of the first oscillator circuit in response to an input signal;
a third transistor being connected between the first transistor and the first voltage, being set to be in the electrical connection state during the oscillation of the first oscillator circuit or the electrical disconnection state during no oscillation of the first oscillator circuit, and decreasing a voltage between a gate and a source of the first transistor; and
a fourth transistor being connected in parallel with the second transistor between the output node and the second voltage, and being set to be in the electrical connection state during no oscillation of the first oscillator circuit.

14. The semiconductor device according to claim 13,
wherein each of the first to third logic gates further includes:
a fifth transistor being connected between the first transistor and the output node, and being set to be in the electrical connection state during the oscillation of the first oscillator circuit.

15. The semiconductor device according to claim 13,
wherein the second oscillator circuit includes
fourth logic gates being connected in series and having levels, the number of which is the same as the number of levels of the plurality of logic gate groups of the first oscillator circuit,
wherein the fourth logic gate includes:
a fifth transistor and a sixth transistor being connected in series via an output node between the first voltage and the second voltage, and being complementarily set to be in an electrical connection or electrical disconnection state during the oscillation of the second oscillator circuit in response to an input signal;
a seventh transistor being connected between the fifth transistor and the first voltage, being set to be in the electrical connection state during the oscillation of the second oscillator circuit or the electrical disconnection state during no oscillation of the second oscillator circuit, and decreasing a voltage between a gate and a source of the fifth transistor;
an eighth transistor being connected in parallel with the sixth transistor between the output node and the second voltage, and being set to be in the electrical connection state during no oscillation of the second oscillator circuit;
a ninth transistor being connected between the fifth transistor and the output node; and
a tenth transistor being connected between the sixth transistor and the output node.

16. The semiconductor device according to claim 15,
wherein the ninth transistor is set to be in the electrical connection state during the oscillation of the second oscillator circuit and during no oscillation of the second oscillator circuit, and
wherein the tenth transistor is set to be in the electrical connection state during the oscillation of the second oscillator circuit or the electrical disconnection state during no oscillation of the second oscillator circuit.
